(19) United States
(12) Patent Application Publication
(10) Pub. No.: US 2005/0274876 A1
(43) Pub. Date: Dec. 15, 2005

(54) Voltage monitoring apparatus and laser equipment with the same

(75) Inventors: Ji-Hun Yim, Yongin-si (KR); Jung-Ho Kim, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/133,611

(22) Filed: May 20, 2005

(30) Foreign Application Priority Data
Jun. 11, 2004 (KR) 2004-42807

(51) Int. Cl. H01L 31/00

(52) U.S. Cl. 250/214.1

(57) ABSTRACT

An apparatus for monitoring a voltage received from a laser system comprises a voltage detector for detecting a voltage level outputted from the laser system, a controller for determining the voltage level outputted from the voltage detector, and outputting an alarm control signal if the voltage level is not equal to a reference voltage, a display for displaying the voltage level using a control signal outputted from the controller, and an input part for inputting the reference voltage to the controller.

### CROSS-REFERENCE TO RELATED APPLICATION

This application claims priority to Korean Patent Application No. 2004-42807, filed Jun. 11, 2004, the disclosure of which is incorporated herein by reference in its entirety.

### TECHNICAL FIELD

The present invention relates to an apparatus for manufacturing a semiconductor device, and more particularly, to a voltage monitoring apparatus capable of displaying a voltage level that indicates an alignment state of a chuck for loading a wafer, and a laser system having the same.

### BACKGROUND

In general, a single wafer with a plurality of semiconductor chips designed thereon is manufactured through several repetitive processes. A semiconductor device, such as DRAM, includes a redundancy circuit for repairing a locally defective cell that may be produced during a process of manufacturing the semiconductor device. Most DRAMs are formed with several fuses to utilize the redundancy circuit. After the semiconductor chip is manufactured, the semiconductor chip is subjected to a laser repair process. During the laser repair process, the fuses of the semiconductor chip may be cut, if necessary. The fuses are cut by a laser beam, and a laser system is provided to precisely radiate the laser beam to the fuse.

A conventional laser system includes a first laser source and a second laser source, a plurality of mirrors, a beam interference module, an X-receiver, a Y-receiver, a wafer chuck, a Z-stage, and a system controller. To cut several fuses formed on the semiconductor chip, the wafer with a plurality of semiconductor chips is loaded on the wafer chuck. A laser beam is irradiated from the first laser source through the Z-stage to a specific fuse among several fuses formed on the semiconductor chip, whereby the fuse exposed to the laser beam is cut. To accurately guide the laser beam to the specific fuse, the Z-stage must be accurately aligned to the specific fuse. If the Z-stage is not accurately aligned to the specific fuse, the specific fuse may not be accurately cut or an unwanted fuse may be cut. Then, the semiconductor chip becomes useless.

Accordingly, the beam interference module and the second laser source are utilized to accurately align the Z-stage for cutting the specific fuse of the semiconductor chip. The beam interference module and the second laser source are controlled by the system controller. The second laser source irradiates a position monitoring laser beam. The position monitoring laser beam is reflected by reflectors mounted to the Z-stage. The reflected laser beam is incident onto the X-receiver and Y-receiver through the beam interference module.

The X-receiver and Y-receiver convert the incident laser beam into an electrical signal in the form of voltage that is input to the system controller. The system controller measures the input voltage to determine positions X, Y of the Z-stage and the wafer chuck. If the voltage inputted to the system controller is lower or higher than a reference voltage, the system controller cannot accurately determine the position of the Z-stage and the wafer chuck. The inaccurate determination of the position of the Z-stage and the wafer chuck may cut an unwanted fuse. When performing periodical preventive maintenance to prevent cutting the unwanted fuse, an operator measures the voltage inputted to the system controller by use of a digital voltage meter. However, the frequent preventive maintenance using such manual process may lower productivity.

### SUMMARY OF THE INVENTION

In general, exemplary embodiments of the present invention include voltage monitoring apparatus capable of automatically displaying voltage input to a system controller, such that an operator can readily determine an alignment state of a Z-stage or wafer chuck, thereby improving or maximizing its productivity. Exemplary embodiments also include a laser system which employs such voltage monitoring apparatus.

In one exemplary embodiment of the present invention, an apparatus for monitoring a voltage received from a laser system comprises a voltage detector for detecting a voltage level outputted from the laser system, a controller for determining the voltage level outputted from the voltage detector, and outputting an alarm control signal if the voltage level is not equal to a reference voltage, a display for displaying the voltage level using a control signal outputted from the controller, and an input part for inputting the reference voltage to the controller.

In another exemplary embodiment of the present invention, a laser system comprises a wafer chuck for loading a wafer, a Z-stage moving two dimensionally on the wafer chuck, each of first and second mirrors formed vertically at a side of the wafer chuck, a laser beam source for generating a laser beam, a beam interference module for radiating the laser beam supplied from the laser beam source onto the first and second mirrors, and focusing and emitting the laser beam reflected from the first and second mirrors, a plurality of receivers for receiving the laser beam emitted from the beam interference module and transforming the laser beam into an electrical signal, a system controller for receiving the electrical signal outputted from the receivers to align the wafer chuck, and a voltage monitoring apparatus.

In one exemplary embodiment of the present invention, the voltage monitoring apparatus comprises a voltage detector for detecting a voltage level outputted from the laser system, a controller for determining the voltage level outputted from the voltage detector, and outputting an alarm control signal if the voltage level is not equal to a reference voltage, a display for displaying the voltage level using a control signal outputted from the controller, and an input part for inputting the reference voltage to the controller.

In still another exemplary embodiment of the present invention, a method for laser repairing of semiconductor devices comprises inputting a reference voltage, irradiating a laser beam by a laser device, detecting a voltage level using the laser beam, the voltage level being indicative of a status of an alignment of a Z-stage and a wafer chuck, displaying the voltage level on a display, and generating an alarm if the voltage level is not equal to the reference voltage.

These and other exemplary embodiments, aspects, features and advantages of the present invention will become apparent from the following detailed description of exemplary embodiments, which is to be read in connection with the accompanying drawings.

### BRIEF DESCRIPTION OF THE DRAWINGS

FIG. 1 is a block diagram schematically depicting a voltage monitoring apparatus according to an exemplary embodiment of the present invention.

FIG. 2 is a plan view of a display and an input part shown in FIG. 1.

FIG. 3 is a perspective view of a laser system having a voltage monitoring apparatus according to an exemplary embodiment of the present invention.

FIG. 4 is an exploded perspective view depicting laser splitting and focusing means configured in a beam interference module in FIG. 3.

### DESCRIPTION OF EXEMPLARY EMBODIMENTS

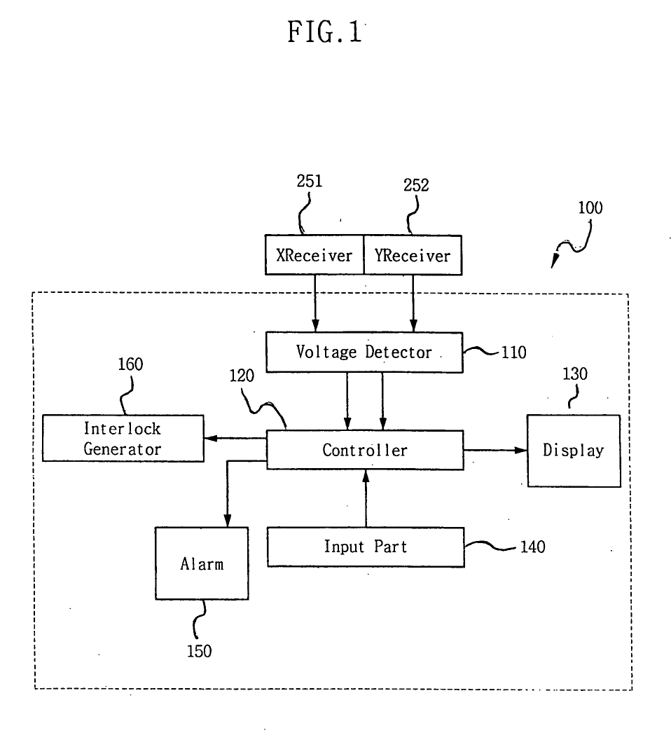

The present invention will now be described more fully hereinafter with reference to the accompanying drawings, in which exemplary embodiments of the invention are shown. This invention may, however, be embodied in different forms and should not be construed as limited to the exemplary embodiments set forth herein. Rather, these exemplary embodiments are provided so that this disclosure will be thorough and complete, and will fully convey the scope of the invention to those skilled in the art. FIG. 1 is a block diagram schematically depicting a voltage monitoring apparatus 100 according to an exemplary embodiment of the present invention. Referring to FIG. 1, the voltage monitoring apparatus 100 includes a voltage detector 110, a controller 120, a display 130, an input part 140, an alarm 150, and an interlock generator 160. The voltage detector 110 detects voltage levels outputted from an X-receiver 251 and a Y-receiver 252 of a laser system, and outputs the voltage levels to the controller 120. The X-receiver 251 and Y-receiver 252 receive a laser beam through a beam interference module of the laser system to output a desired voltage. For example, if the beam interference module of the laser system normally operates and a wafer chuck 200 or a Z-stage 210 of the laser system is aligned, the receivers 251 and 252 output a voltage having a range of about 1.2 V through about 1.3 V to the voltage detector 110.

The controller 120 outputs a display control signal to the display 130 for displaying the voltage levels outputted from the voltage detector 110. In addition, the controller 120 compares voltage levels outputted from the voltage detector 110 with a reference voltage. The controller 120 counts the number of times that the voltage levels are not equal to a reference voltage or a reference voltage within a range of reference voltages inputted through the input part 140, and then outputs a display control signal to the display 130 for displaying the number of times. If the number of times that the voltage levels is not equal to a reference voltage or a reference voltage within a range of reference voltages is beyond a predetermined frequency, the controller 120 outputs an alarm control signal to the alarm 150 and an interlock control signal to the interlock generator 160 for stopping the laser system. The voltage monitoring apparatus 100 may further include a power source (not shown) for supplying power to the controller 120 and the display 130.

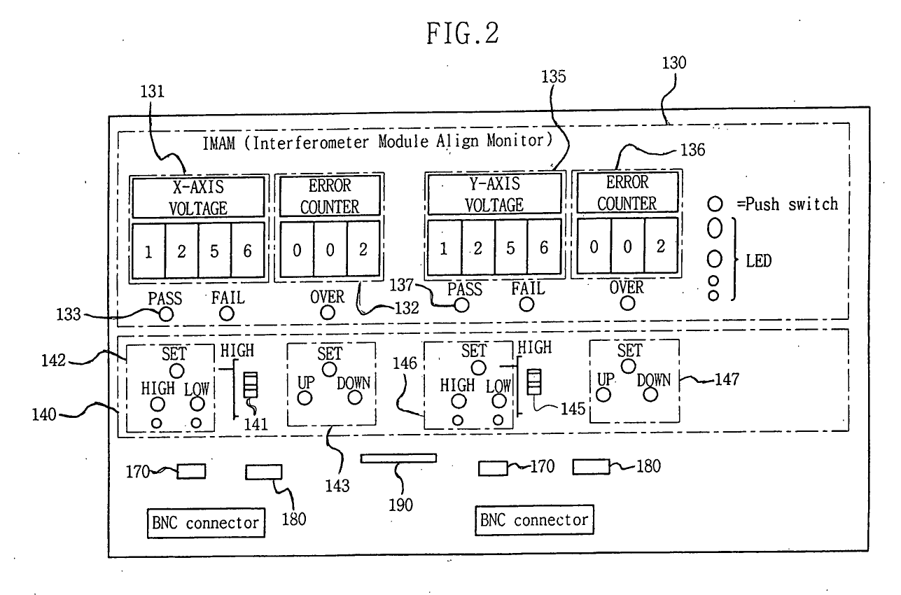

FIG. 2 is a plan view of the display 130 and the input part 140 shown in FIG. 1. The display 130 includes a first display window 131, a second display window 132, and a plurality of light emitting lamps 133 for the X-receiver 251. The display 130 also includes a first display window 135, a second display window 136, and a plurality of light emitting lamps 137 for the Y-receiver. Each of the first display windows 131, 133 displays each voltage level of the X-receiver 251 and the Y-receiver 252, respectively. The second display window 132 for the X-receiver counts and displays the number of times that the voltage level is not equal to a reference voltage or a reference voltage within a range of reference voltages inputted from the input part 140.

The plurality of light emitting lamps 133 shows whether the voltage level outputted from the voltage detector 110 is equal to a reference voltage or a reference voltage within a range of reference voltages or the voltage level outputted from the voltage detector 110 is not equal to a reference voltage or a reference voltage within a range of reference voltages. For example, the first and second display windows 131, 132, 135 and 136 may include a 7-segment LED display. The light emitting lamp 133 may include an LED.

The input part 140 positioned under the display 130 includes a first switch 141, a second switch 142 and a third switch 143 for the X-receiver. The input part 140 also includes a first switch 145, a second switch 146, and a third switch 147 for the Y-receiver. Each of the first switches 141, 145 selects input of each upper or lower limit value of reference voltages of each of the X-receiver 251 and Y-receiver 252, respectively. The second switches 142, 146 set the upper or lower limit value of reference voltages selected by the first switches 141, 145, respectively. The third switches 143, 147 set the number of times that the voltage level outputted from the voltage detector 110 is not equal to a reference voltage or a reference voltage within a range of reference voltages. For example, each of the first switches 141, 145 may include a toggle switch, and the second and third switches 142, 143, 146, and 147 may include a touch pad, respectively. The input part 140 may further include a set switch for resetting the range of reference voltages.

The voltage monitoring apparatus further includes a plurality of input connectors 170 (e.g., Bayonet Beil-Concelman connector or British Naval Connector) connected to various cables, which are connected to the X-receiver 251 and the Y-receiver 252, and an output connector 180 for outputting the interlock signal output from the interlock generator 160. The voltage monitoring apparatus further includes a power connector 190 connected to a power cable for supplying the power to a power section.

The voltage monitoring apparatus according to an exemplary embodiment of the present invention automatically detects the output voltage outputted from the X-receiver 251 and the Y-receiver 252 of the laser system, and displays the detected output voltage inputted through the system controller 260. As a result, the operator easily determines the alignment state of the Z-stage or the wafer chuck, thereby improving or maximizing its productivity.

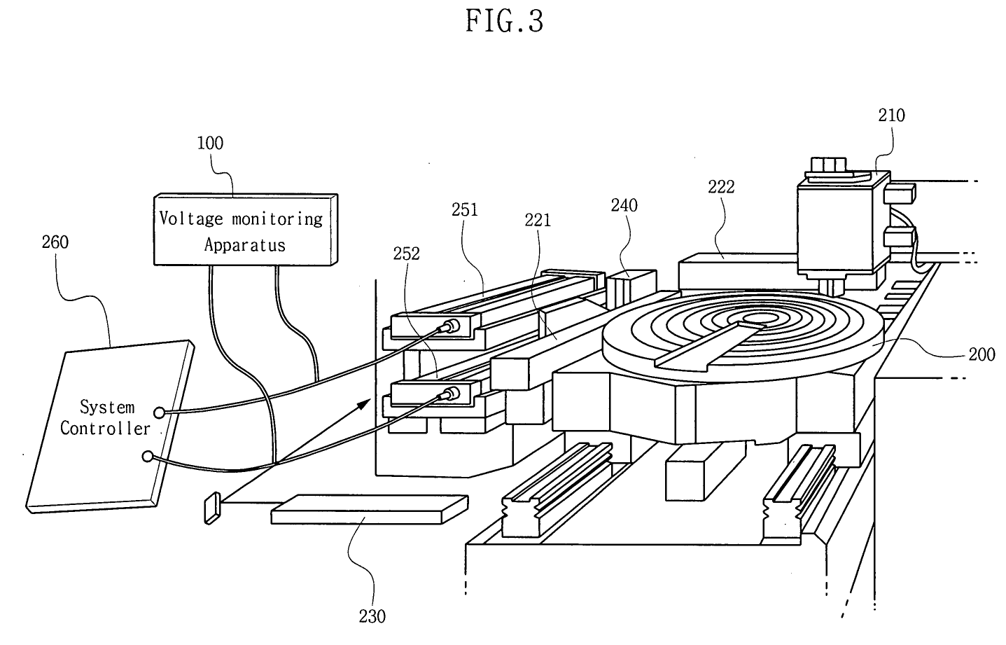

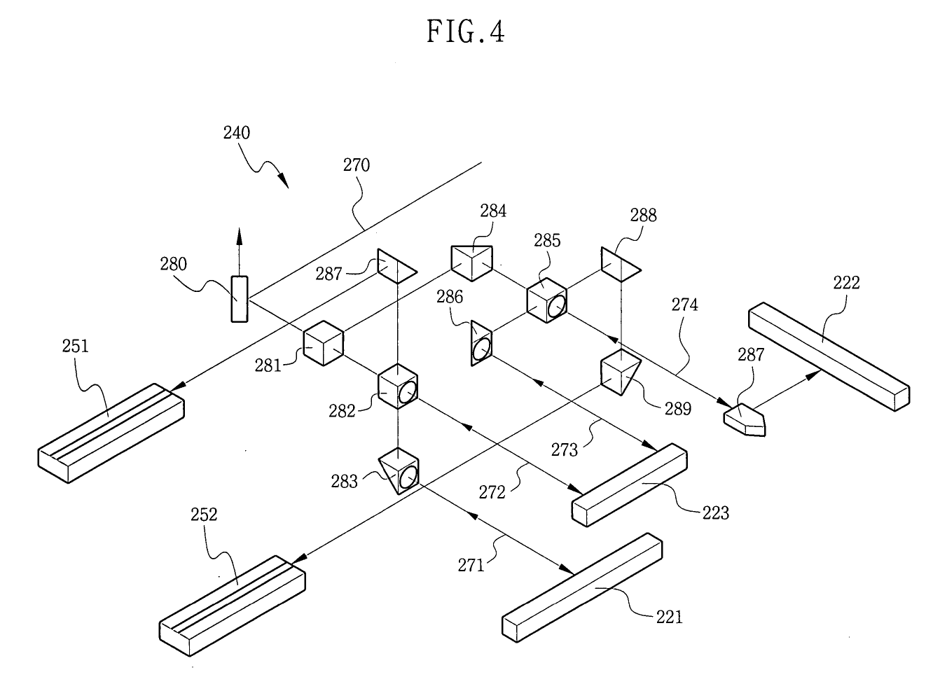

A laser system having the voltage monitoring apparatus according to an exemplary embodiment of the present invention will now be described. FIG. 3 shows a perspective view of the laser system having the voltage monitoring apparatus according to an exemplary embodiment of the present invention. FIG. 4 shows an exploded perspective view depicting laser splitting and focusing means configured in the beam interference module 240 in FIG. 3.

Referring to FIG. 3, the laser system includes a wafer chuck 200, a Z-stage 210, first and second mirrors 221 and 222, a laser beam source 230, a beam interference module 240, the X-receiver 251 and the Y-receiver 252, a system controller 260, and the voltage monitoring apparatus 100. The wafer chuck 200 loads a wafer with a plurality of semiconductor chips formed thereon. The Z-stage 210 moves two-dimensionally over the wafer chuck 200 to cut a fuse formed on the wafer. Each of the first and second mirrors 221 and 222 is vertically formed at a side of the wafer chuck 200. The laser beam source 230 generates a laser beam. The beam interference module 240 radiates the laser beam supplied from the laser beam source onto the first and second mirrors 221 and 222, and focuses and emits the laser beam reflected from the first and second mirrors 221 and 222. The X-receiver 251 and Y-receiver 252 receives the laser beam emitted from the beam interference module 240 and transforms the laser beam into the electrical signal in the form of voltage.

The system controller 260 receives the electrical signal outputted from the X-receiver 251 and Y-receiver 252 to align the wafer chuck 200. The voltage monitoring apparatus 100 monitors the voltage signal outputted from the X-receiver 251 and Y-receiver 252 to the system controller 260 to monitor the alignment state of the wafer chuck 200 or the beam interference module 240. The wafer chuck 200 is adapted to move perpendicular to the Z stage 210. The Z stage 210 comprises cutting means such as fuse cutting laser beam for cutting the fuse of the semiconductor chip formed on the wafer.

To align the wafer chuck 200 in the X axis and the Y axis, the first and second mirrors 221 and 222 reflect the laser beam emitted through the beam interference module 240 onto the beam interference module 240 at X-axis and Y-axis side walls of the wafer chuck 200. For example, the first and second mirrors 221 and 222 are referred to as an X-axis datum mirror and a Y-axis datum mirror respectively. The Z-stage 210 comprises a Z-axis mirror 223 (FIG. 4) for reflecting the laser beam radiated from the beam interference module 240.

Referring to FIG. 4, the beam interference module 240 includes, for example, a plurality of prisms, splitters and mirrors. The beam interference module 240 divides a source laser beam 270 supplied from the laser beam source 230 into a plurality of laser beams to emit the laser beam onto the first and second mirrors 221 and 222. The beam interference module 240 focuses the laser beam reflected from the first and second mirrors 221 and 222.

The source laser beam 270 radiated from the laser source 230 is divided into first and second laser beams 271 and 272 by reflecting off a turning mirror 280, and by passing through first and second splitters 281 and 282 and a first prism 283. The source laser beam 270 is divided into third and fourth laser beams 273 and 274 by passing through the fist splitter 281, a second prism 284, a third splitter 285 and a third prism 286. Two pairs of divided laser beams 271 through 274 are reflected onto the first and second mirrors 221 and 222. The first and second laser beams 271 and 272 of the four returned laser beams are focused as an X-axis receiving laser beam by passing through second and fourth prisms 282 and 287. The third and fourth laser beams 273 and 274 are focused as a Y-axis receiving laser beam by passing through the third splitter 285 and fifth and sixth prisms 288 and 289.

For example, the four laser beams dispersed through the beam interference module 240 are divided into reference laser beams and measuring laser beams with respect to the X-axis and Y-axis. Hereinafter, paths of the four laser beams according to an exemplary embodiment of the present invention will be described. The first laser beam 271 supplied from the beam interference module 240, which is the X-axis reference laser beam, is incident upon the first X-axis mirror 221 formed at the side of the wafer chuck 200. The first laser beam 271 is then reflected to the beam interference module 240 to provide the X-axis reference point of the Z-stage 210.

The second and third laser beams 272 and 273, which are the X-axis measuring laser beam and the Y-axis reference laser beam, respectively, are incident upon the Z-stage 210. Then the second and third laser beams 272 and 273 are reflected to the beam interference module 240. The first and second laser beams 271 and 272 of the Z-stage 210 are focused onto the beam interference module 240 and are incident upon the X-receiver 251.

The fourth laser beam 274, which is the Y-axis measuring laser beam, is incident upon the second mirror 222, is reflected to the beam interference module 240, and is focused with the third laser beam 273 to be incident upon the Y-receiver 252. Therefore, the first and second laser beams 271 and 272 provide the X-axis position of the Z-stage 210, while the third and fourth laser beams 273 and 274 provide the Y-axis position of the wafer chuck 200.

The maximum reflectance of the first and second laser beams 271 and 272 and the third and fourth laser beams 273 and 274 indicates that the prisms, the slitters and the mirrors in the beam interference module 240 and the Z-stage 210 are accurately aligned.

The X-receiver 251 and Y-receiver 252 receive the laser beam focused by the beam interference module 240 and transform the laser beam into the electrical signal. The X-receiver 251 and Y-receiver 252 transform a quantity of light of the laser beam supplied from the beam interference module 240 into the electrical signal by use of a photoelectric effect and output the electrical signal to the system controller 260.

If the prisms, the splitters and the mirrors are accurately aligned in the beam interference module 240, the electrical signal is equal to a reference voltage within a range of reference voltages (e.g., about 1.2V through about 1.3V). If the prisms, the splitters and the mirrors are not accurately aligned in the beam interference module 240, the electrical signal is not equal to a reference voltage within the range of reference voltages (e.g., below 1.2V). If the electrical signal is not equal to a reference voltage within the range of reference voltages, the voltage monitoring apparatus 100 sounds the alarm through the alarm 150 to notify the operator of an improper alignment of the beam interference module 240 or the wafer chuck 200.

The operator can adjust angles of the prisms, the splitters and the mirrors in the beam interference module 240. While adjusting the angles of the prisms, the splitters and the mirrors in the beam interference module 240, the operator can continuously check the electrical signal. If the electric signal reaches the reference voltage, angular adjustment of the lenses in the beam interference module 240 may be stopped.

Accordingly, the laser system including the voltage monitoring apparatus according to an exemplary embodiment of the present invention automatically displays the input voltage inputted to the system controller 260 to enable the operator to determine the alignment state of the Z-stage 210 or wafer chuck 200, thereby improving or maximizing its productivity.

Although exemplary embodiments have been described herein with reference to the accompanying drawings, it is to be understood that the present invention is not limited to such exemplary embodiments, and that various other changes and modifications may be affected therein by one of ordinary skill in the related art without departing from the scope or spirit of the invention. All such changes and modifications are intended to be included within the scope of the invention as defined by the appended claims.

1. An apparatus for monitoring a voltage received from a laser system, the apparatus comprising:
a voltage detector for detecting a voltage level outputted from the laser system;
a controller for determining the voltage level outputted from the voltage detector, and outputting an alarm control signal if the voltage level is not equal to a reference voltage;
a display for displaying the voltage level using a control signal outputted from the controller; and
an input part for inputting the reference voltage to the controller.

2. The apparatus according to claim 1, wherein the reference voltage includes a voltage within a range of reference voltages.

3. The apparatus according to claim 1, further comprising an alarm for receiving the alarm control signal outputted from the controller to output an alarm.

4. The apparatus according to claim 1, further comprising an interlock generator for receiving an interlock control signal outputted from the controller to stop operating the laser system.

5. The apparatus according to claim 1, wherein the display comprises:
a first display window for displaying the voltage level;
a second display window for counting and displaying the number of times that the voltage level is not equal to the reference voltage, wherein the reference voltages are inputted through the input part; and
a plurality of light emitting lamps for displaying whether the voltage level outputted from the voltage detector is equal to reference voltage or the voltage level outputted from the voltage detector is not equal to the reference voltage.

6. The apparatus according to claim 5, wherein the first and second display windows include a 7-segment LED display.

7. The apparatus according to claim 5, wherein the light emitting lamp includes an LED.

8. The apparatus according to claim 2, wherein the input part comprises:
a first switch for selecting the range of reference voltages;
a second switch for setting the range of reference voltages selected by the first switch; and
a third switch for setting a number of times that the voltage level outputted from the voltage detector is not equal to the reference voltage within the range of reference voltages.

9. The apparatus according to claim 8, wherein the first switch includes a toggle switch.

10. The apparatus according to claim 8, wherein the second and third switches include a touch pad, respectively.

11. The apparatus according to claim 2, wherein the input part further includes a set switch for resetting the range of reference voltages.

12. A laser system comprising:
a wafer chuck for loading a wafer;
a Z-stage moving two dimensionally on the wafer chuck;
each of first and second mirrors formed vertically at a side of the wafer chuck;
a laser beam source for generating a laser beam;
a beam interference module for radiating the laser beam supplied from the laser beam source onto the first and second mirrors, and focusing and emitting the laser beam reflected from the first and second mirrors;
a plurality of receivers for receiving the laser beam emitted from the beam interference module and transforming the laser beam into an electrical signal;
a system controller for receiving the electrical signal outputted from the receivers to align the wafer chuck; and
a voltage monitoring apparatus comprising: a voltage detector for detecting a voltage level outputted from the laser system; a controller for determining the voltage level outputted from the voltage detector, and outputting an alarm control signal if the voltage level is not equal to a reference voltage; a display for displaying the voltage level using a control signal outputted from the controller; and an input part for inputting the reference voltage to the controller.

13. A method for laser repairing of semiconductor devices, the method comprising:
inputting a reference voltage;
irradiating a laser beam by a laser device;
detecting a voltage level using the laser beam, the voltage level being indicative of a status of an alignment of a Z-stage and a wafer chuck;
displaying the voltage level on a display; and
generating an alarm if the voltage level is not equal to the reference voltage.
